(19) United States
(12) Patent Application Publication
(10) Pub. No.: US 2019/0334019 A1
(43) Pub. Date: Oct. 31, 2019

(54) TOP STRUCTURE OF INSULATED GATE BIPOLAR TRANSISTOR (IGBT) WITH IMPROVED INJECTION ENHANCEMENT

(71) Applicant: Hunteck Semiconductor (Shanghai) Co.,Ltd., Shanghai (CN)

(72) Inventor: Jun Hu, San Bruno, CA (US)

(21) Appl. No.: 16/382,164

(22) Filed: Apr. 11, 2019

Related U.S. Application Data
(60) Provisional application No. 62/656,348, filed on Apr. 11, 2018.

(51) Int. Cl. H01L 29/739; H01L 27/06; H01L 29/423; H01L 29/66; H01L 29/40

(52) U.S. Cl. CPC H01L 29/7397; H01L 27/0623; H01L 29/401; H01L 29/66348; H01L 29/42356

(57) ABSTRACT

This invention discloses an insulating gate bipolar transistor (IGBT) device that comprises a substrate including a semiconductor layer of a first conductivity type on the top of the bottom semiconductor layer of a second conductivity type and supporting buried layer of a second conductivity type disposed below a top layer of the first conductivity type. The IGBT further has a plurality of MOS transistor cells each having a planar gate disposed on a top surface of the top layer wherein each of the planar gates extended between two adjacent body regions of the second conductivity type encompassing a emitter region of the first conductivity type wherein the body regions and emitter regions are near a top portion of the top layer of the first conductivity type. The IGBT further includes a trench gate vertically extending from the top portion of the top layer adjacent to a body region downwardly to the buried layer of the second conductivity. Furthermore, the device includes lightly doped region in the top layer of the first conductivity type that is disposed next to the trench gate below the body region of the second conductivity type above the buried layer of the second conductivity type.

### CROSS REFERENCE TO RELATED APPLICATIONS

This application is a Non-Provisional Application which claims the Priority Date of previously filed Provisional Applications 62/656,348 filed on Apr. 11, 2018 and the disclosures made in Application 62/656,348 are hereby incorporated by reference in this Application.

### FIELD OF THE INVENTION

The invention relates generally to semiconductor power devices. More particularly, this invention relates to new configurations and methods for manufacturing improved insulated gate bipolar transistor (IGBT) device with new top structure with improved injection enhancement.

### DESCRIPTION OF THE RELATED ART

Conventional technologies to configure and manufacture semiconductor power devices operating at higher breakdown voltages are still confronted with existing technical difficulties and limitations. Particularly, the configurations and designs of the top structure of the insulated gate bipolar transistor (IGBT) power devices are limited by the trade-off between Vcesat and the breakdown voltage and the trade-off between the conduction loss and the switch loss. In order to optimize the trade-offs by increasing the injection from the emitter side, some of the IGBT devices require dual trench processes and higher cell density thus causing the concerns of wafer warpage. As will be further discussed below, several of the conventional IGBT structures and configurations are still confronted with such difficulties and limitations.

There are different configurations of IGBT devices in order to achieve a high injection from the emitter side, such as planar gate IGBT devices and IGBT device of the trench gate type. As disclosed in U.S. Pat. No. 6,724,043, the IGBT devices are shown in FIGS. 1A and 1B. Both configurations shown in FIGS. 1A and 1B include a second gate G2 disposed over a p-type well region (20 or 120) to form a MOSFET channel between the first well region (22 or 122) and the drift region (24 or 124). Since the p-type well region 20 (also similar for p-type well region 120) has a P region 20a in the main current path and a region 20b extends upwardly to the surface 18 of the structure. The device structures require high temperature thermal treatment to form the p column to connect to the buried P layer. The high temperature thermal treatment makes the fabrication process more complicated and often degrades the device performance. In addition, for the planar gate IGBT device, the second gate G2 wastes active device area.

FIG. 1C shows the configuration of another IGBT device disclosed in a published Patent Application US2015/0035003 A1. The configuration as shown requires a dual trench manufacturing processes thus adversely affecting the production costs. Furthermore, the dual trenches often lead to the reliability concerns due to the problems of wafer warpage caused by high trench density when the dual trench configuration is implemented. Additionally, the shift of breakdown voltage BV during a switch mode is also an issue required to be resolved in this device.

For the above reasons, there is a need to provide new device configurations and new manufacturing methods for the IGBT semiconductor power devices to overcome the above discussed difficulties and limitations. Meanwhile, it is desirable that the improved device can provide a shielding P-buried layer to shield the top structure such that the breakdown voltage can be stabilized without being significantly affected by the resistivity of the top layers.

### SUMMARY OF THE PRESENT INVENTION

It is an aspect of the present invention to provide a new and improved device configuration and manufacturing method for providing an insulated gate bipolar transistor (IGBT) power device with a P-buried layer below top N-doped layers as a shield to shield the top layers thus the breakdown voltage is not prevented from be affected by the resistivity variations of the top layers. Thus the design and manufacturing processes of the top structures of the IGBT device have greater degree of freedom and the best tradeoff between a low Vcesat and a high BV is achievable.

Another aspect of the present invention is to provide a new and improved device configuration and manufacturing method for providing a an IGBT power device implemented with a trench gate and a planar gate wherein the trench gate has a lower threshold voltage. There are at least two planar gate MOS transistor cells between every two adjacent trench gates. The trench gate penetrates the P-buried layer and bottom of the trench gate is located in the N-type drift layer. The trench gate is turned on first when a positive voltage is applied to the gates and an inversion layer is formed first on the side wall of the p buried layer thus connecting the N-top and N drift layer followed by turning on of the planar gate.

Specifically, an aspect of the present invention is to provide a new and improved device configuration and manufacturing method for providing an IGBT power device implemented with the lightly doped N-top layer adjacent to trench gate and the highly doped N-imp layer under the planar gate on top of the P-buried layer to improve the ruggedness of the device. When the device is switched off, the lightly doped N-top layer adjacent to the trench gate can be depleted easily, which makes the P body and P buried layer equal-potential very fast and starts to build block voltage immediately. So the risk of BV degradation under high frequency switch mode is significantly reduced.

Briefly in a preferred embodiment this invention discloses an IGBT power device formed on an upper epitaxial layer of a first conductivity type supported on a semiconductor substrate. The IGBT power device comprises a planar gate and a trench gate. The planar gate (PG) is formed on the top surface of the silicon substrate and the planar gate is the control gate of the device. The trench gate is formed with trench polysilicon that is deposited into the trench after the formation of the gate oxide on the trench sidewalls and the bottom surface of the trench. When the positive voltage is applied on the trench gate higher than the Vth of the trench gate, an inversion layer is formed on the side wall of P buried layer and the N top layer is electrically connected to the N-drift layer through the inversion layer. The trench gate has a lower threshold voltage Vth than the planar gate. Therefore, when the device is turned on, the trench gate is turned on before the planar gate is fully turned on. Additionally, the threshold voltage Vth of the trench gate is adjustable by changing the thickness of trench gate oxide and doping concentration of the P buried layer. The planar gate and the trench gate are electrically connected to the gate termination of the IGBT device. Furthermore, the P buried layer is located under the N-top region and N-imp region and is floating. The dopant concentration of P buried layer is lower than the doping of the body region. The doping concentration of the N-top region is very low in order to make sure the N-top region near the sidewall next to the trench gate is depleted very fast when the device is turned off. Specifically, in an embodiment, the N-imp layer is formed by implant and drive in. the distance between N-imp to the trench is more than half pitch of the MOS structure and the doping of N-imp layer is higher than 1e16 cm−3.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIGS. 1A to 1B are cross sectional views showing two different top structures of the conventional IGBT power devices.

FIG. 1C is a cross sectional view of another conventional IGBT device implemented with dual trench configuration.

FIG. 2A is a cross sectional view of a preferred embodiment of the IGBT device of this invention, FIG. 2C shows the P and N doping profile of the device compared with the profile of the conventional IGBTs, FIG. 2D shows the variations of the breakdown voltage (BV) as function of the top layer resistivity and FIG. 2E shows the electron and hole profile of the device when the device is turned on.

FIGS. 3A to 3G are a series of cross sectional views for illustrating the manufacturing processes of devices shown in FIG. 2.

FIG. 4A is a top view and FIGS. 4B to 4E are cross sectional views of the IGBT device along the cross-sectional lines A-A′, B-B′, C-C′ and D-D′ respectively.

FIG. 5A is a three-dimensional perspective view of another three-dimensional embodiment of this invention. FIG. 5B and FIG. 5C are cross sectional views of the three-dimensional IGBT alone the cross-sectional lines A-A′ and B-B′ respectively in the X-Z plane.

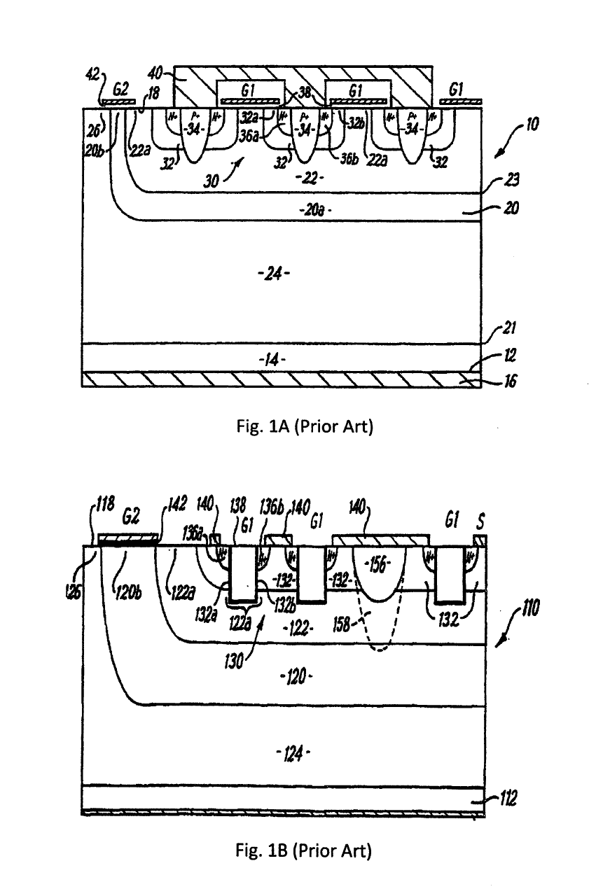

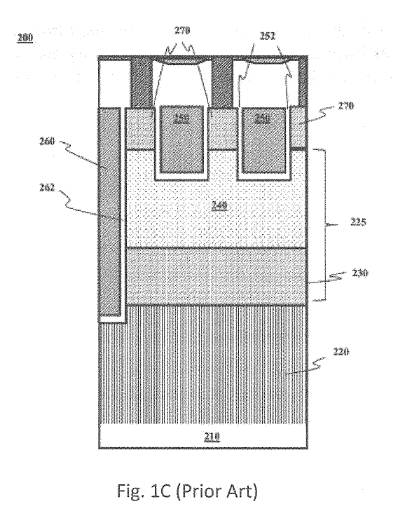

### DETAILED DESCRIPTION OF THE PREFERRED EMBODIMENTS

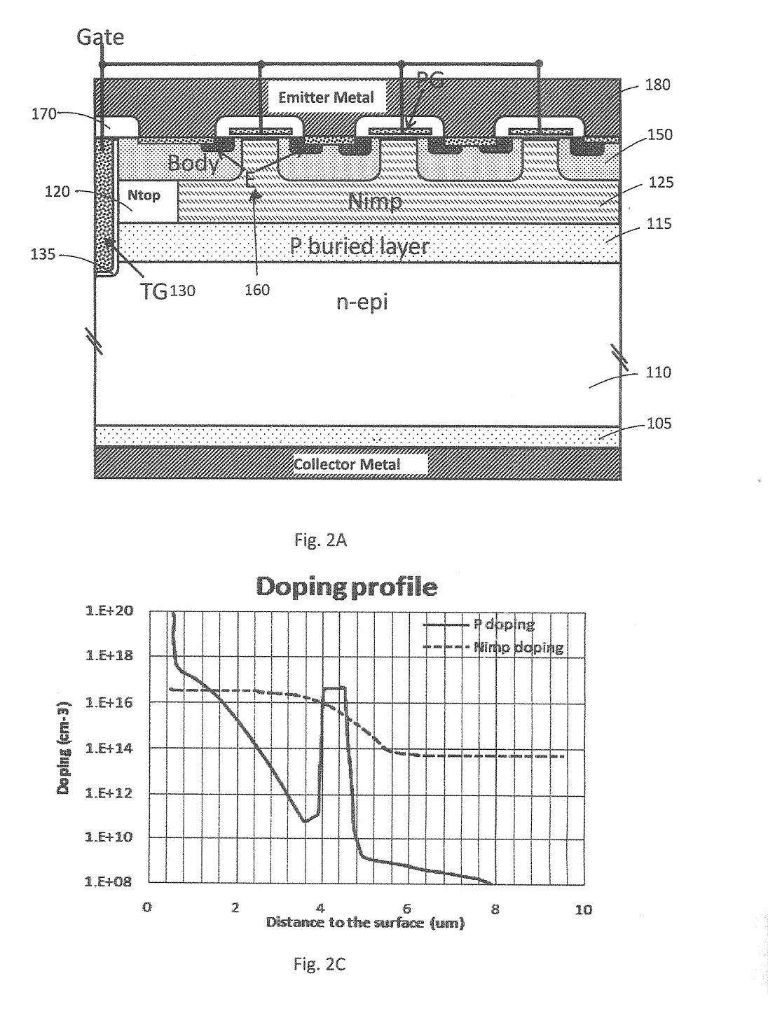

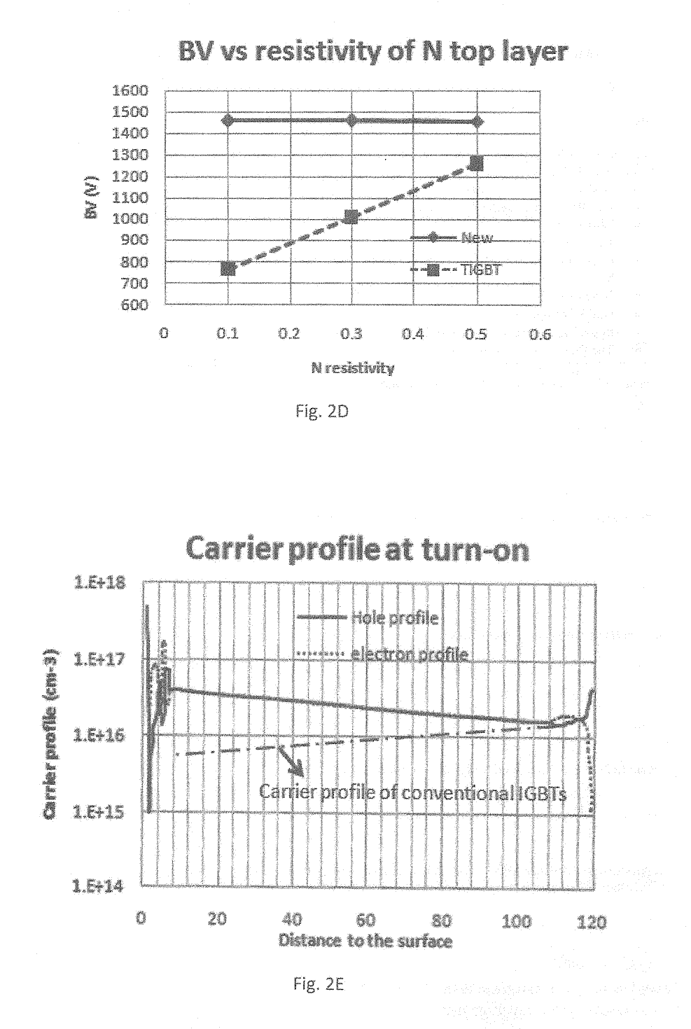

FIG. 2A is a side cross sectional view of an insulated-gate bipolar transistor (IGBT) cell 100 as a preferred embodiment of this invention. The IGBT power device including the transistor cell 100 is formed on a P-type semiconductor substrate 105. In general, the P-type substrate may be referred to as the bottom collector layer. An N-type epitaxial layer 110 is deposited on top of the bottom substrate layer 105. A P-buried layer 115 is formed on top of the N-type epitaxial layer 110 under a top low concentration N-doped N-top layer 120. An N-implant region N-imp layer 125 is then implanted with a higher doping concentration than N-top layer 120.

The IGBT cell 100 further includes a trench gate (TG) 130 formed in a trench with trench sidewalls and bottom surface padded by a gate oxide layer 135. Planar gates (PG) padded by a gate oxide layer 135′ underneath are formed on a top surface of the semiconductor substrate. The planar gate 140 extends laterally on a top surface of the epitaxial layer 110. In some preferred embodiments, there are at least two planar gate MOS transistor cells, e.g. six planar gate MOS transistor cells, between every two adjacent trench gates. The IGBT cell further includes emitter regions 160 encompassed in the body regions 150 disposed underneath the lateral gate 140 below the gate oxide layer 135′ on the top surface of the epitaxial layer 110.

The IGBT device further comprises a top insulation layer 170 with a plurality of contact windows opened through the top insulation layer 170. An emitter contact metal layer 180 is formed on top of the top insulation layer 170. The top emitter metal layer 180 is electrically contact to the body and emitter regions through the contact dopant regions 175 formed as dopant implant regions through the contact windows opened in the top insulation layer 170.

The IGBT device 100 as shown in FIG. 2A has planar gates 140 and trench gate 130. The planar gate 140 has a higher threshold voltage (Vth) than the trench gate 130. As the manufacturing processes will be further shown below, the processing steps only require one trench process. Therefore, a high density trench processes are not required. Furthermore, the pitch size of the MOS structure on the top is not very critical because the resistance of IGBT is dominated by the drift layer. The P buried layer is located under the N-top layer 120 and the N-imp layer 125 with the dopant profiles, as that shown in FIG. 2C, provide shield to the N top layer when the device is turned off. Therefore the N-imp layer 125 can have higher doping concentration than the regular IGBT. The N-top layer 120 has a low doping concentration, e.g., 1e15 cm−3, and the N-imp layer 125 has a high doping concentration of >1e16 cm−3.

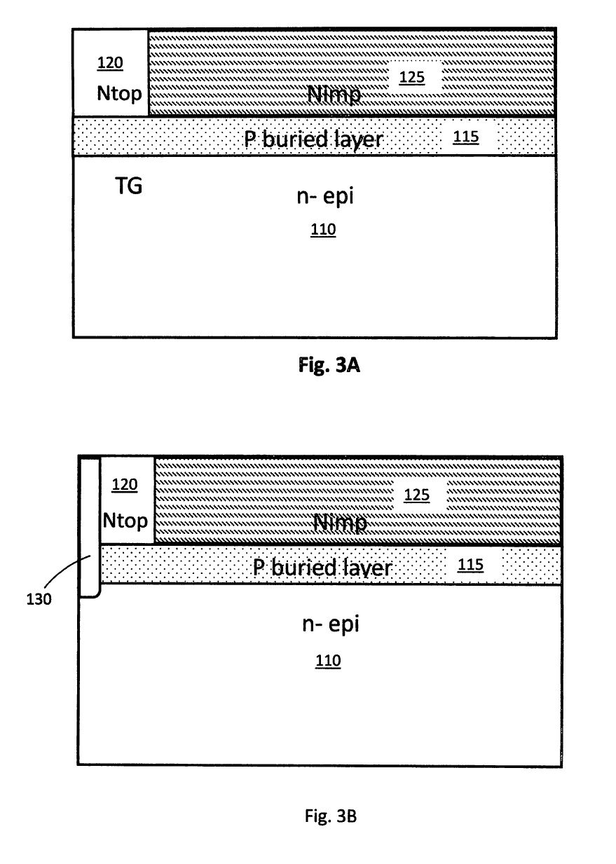

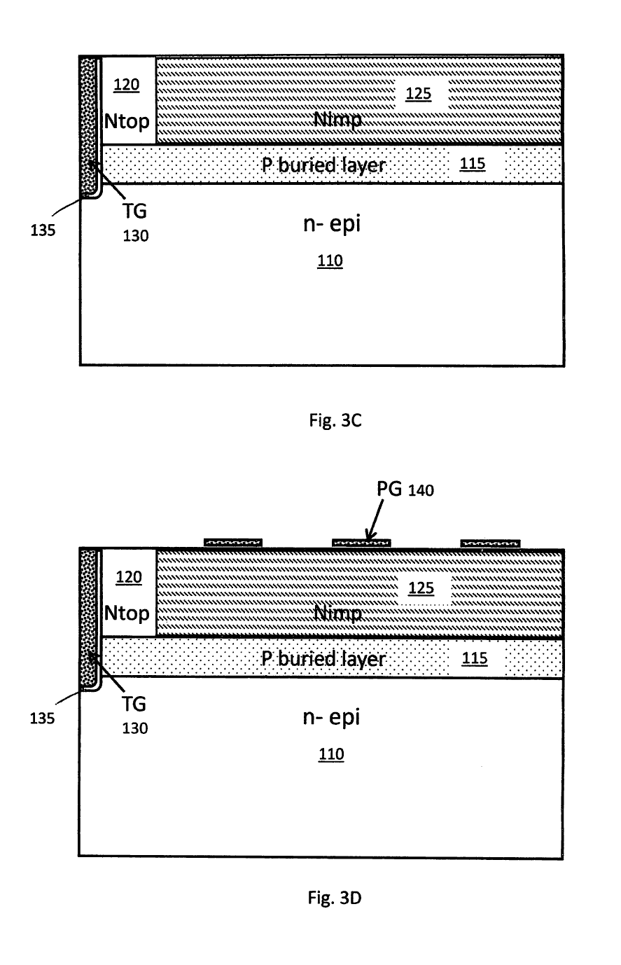

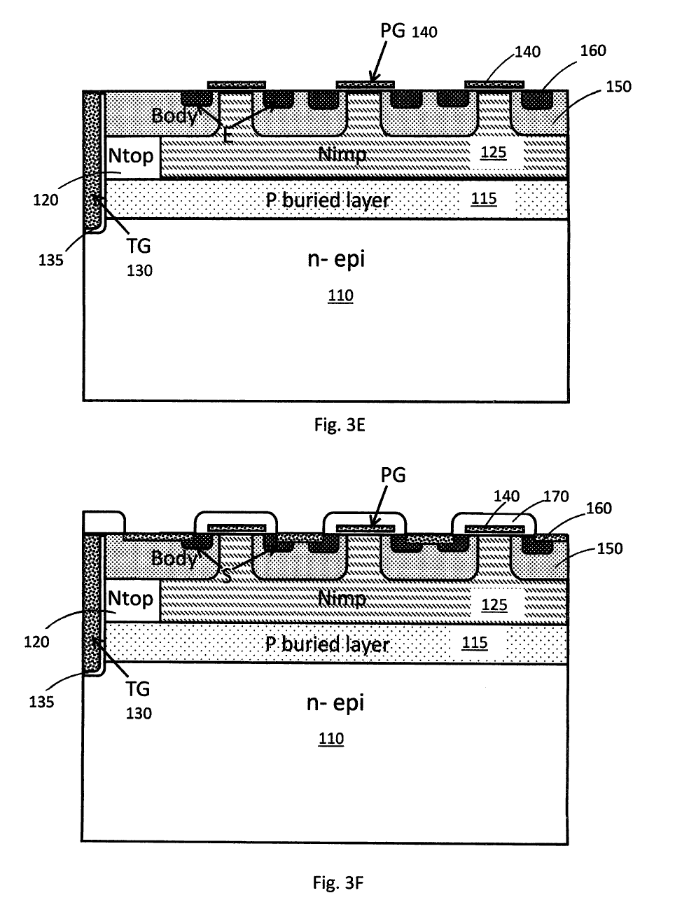

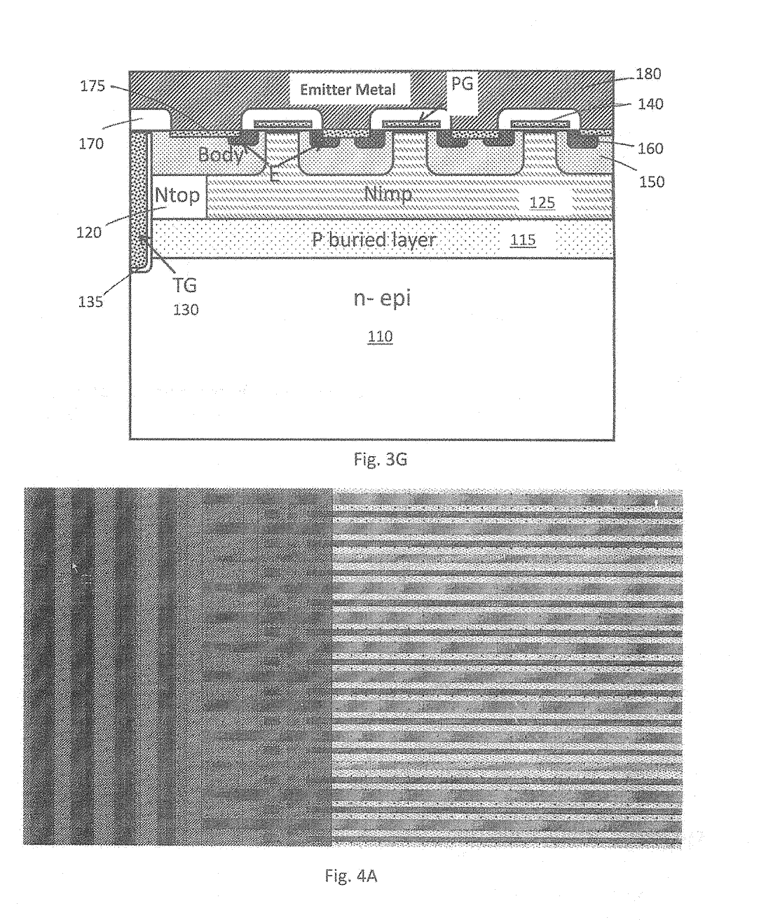

The IGBT device is turned off when the trench gate and planar gate are at ground potential. Because the N-top 120 has a lower doping concentration, the N-top layer can be easily depleted, especially the regions near the sidewall next to the specifically shown). A P buried layer 115 is deposited on top of the N-epitaxial layer 110 functioning as a drift layer wherein the P buried layer 115 can be formed either by epitaxial growth of implant. Then an N-top layer 120 with a low doping concentration is deposited on top of the P buried layer 115 followed by implanting an N-imp region 125 in the N-top layer 120 followed by a drive process. In FIG. 3B a deep trench process is carried out to open a trench 130 through the N-top layer 120, the P-buried layer 115 with a bottom of the trench 130 reaches to an upper portion of the epitaxial layer 110. Then, the trench 130 is filled with a gate conductive material such as filling the trench 130 with polysilicon.

FIGS. 3A-3G are a series of cross sectional views to show the fabrication processes of a semiconductor power device shown in FIG. 2A. In FIG. 3A, an N-epitaxial layer 110 is formed on top of an N-type semiconductor substrate (not specifically shown). A P buried layer 115 is deposited on top of the N-epitaxial layer 110 functioning as a drift layer wherein the P buried layer 115 can be formed either by epitaxial growth of implant. Then an N-top layer 120 with a low doping concentration is deposited on top of the P buried layer 115 followed by implanting an N-imp region 125 in the N-top layer 120 followed by a drive process. In FIG. 3B a deep trench process is carried out to open a trench 130 through the N-top layer 120, the P-buried layer 115 with a bottom of the trench 130 reaches to an upper portion of the epitaxial layer 110. Then, the trench 130 is filled with a gate conductive material such as filling the trench 130 with polysilicon.

In FIG. 3C, a trench gate oxide layer 135 is deposited on the sidewalls and a bottom surface of the trench 130 followed by filling the trench 130 with trench gate (TG) polysilicon for a polysilicon etch back and oxide etch back. In FIG. 3D, a planar gate oxide layer 140 is deposited followed by a planar polysilicon layer 145 on top of the oxide layer 140 then the polysilicon layer 145 and the oxide layer 140 are patterned into planar gates (PG) 140.

In FIG. 3E, body regions 150 are formed by a body dopant implant with a P-type dopant such as boron ions followed by emitter dopant implant of an N-type dopant such as phosphorus ions to form the emitter regions 160 encompassed in the body region. In FIG. 3F, an IDL and BPSD deposition process is carried out over the top surface of the substrate to form a top insulation layer 170 followed by opening in the top insulation layer 170 contact windows above the body regions 150 and emitter regions 160. A contact implant is carried out to implant the contact regions 175 below the contact windows. In FIG. 3G, a top metal layer is formed and patterned into an emitter contact metal 180 to contact the contact regions 175 in the upper portion of the emitter region 160 and body region 150 through the contact windows opened in the top insulation layer 170.

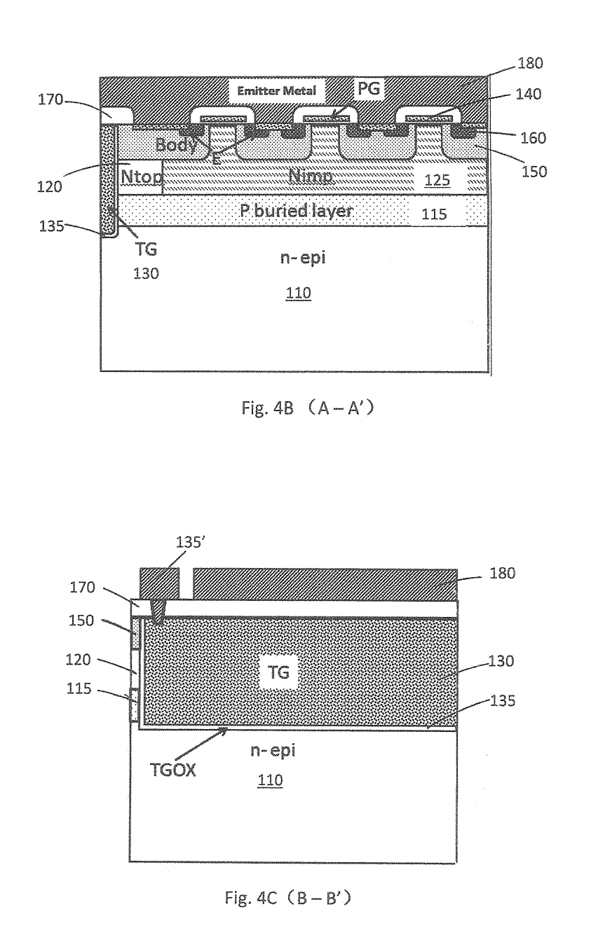

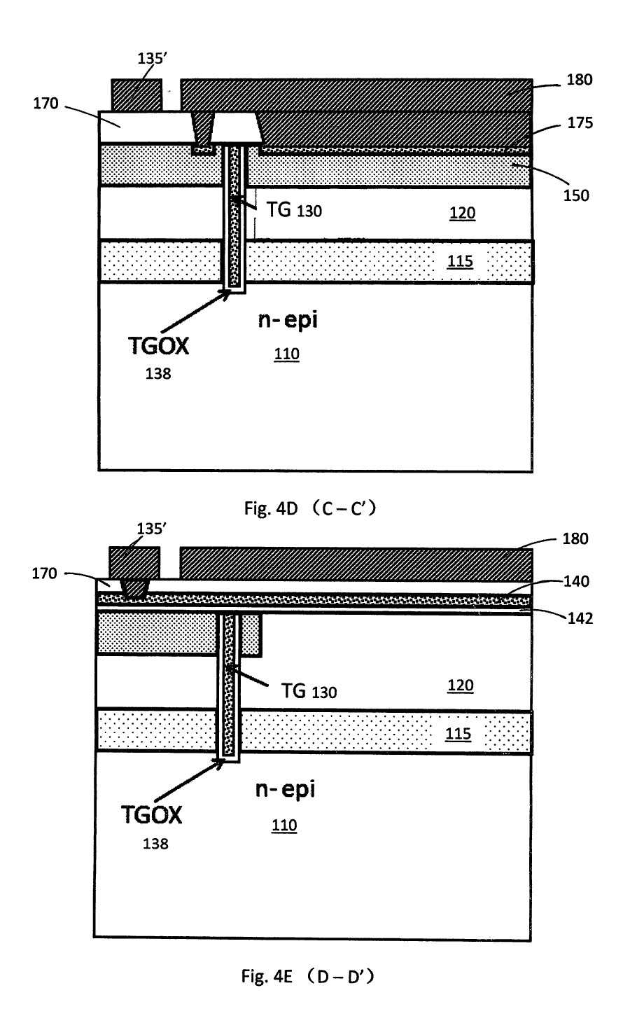

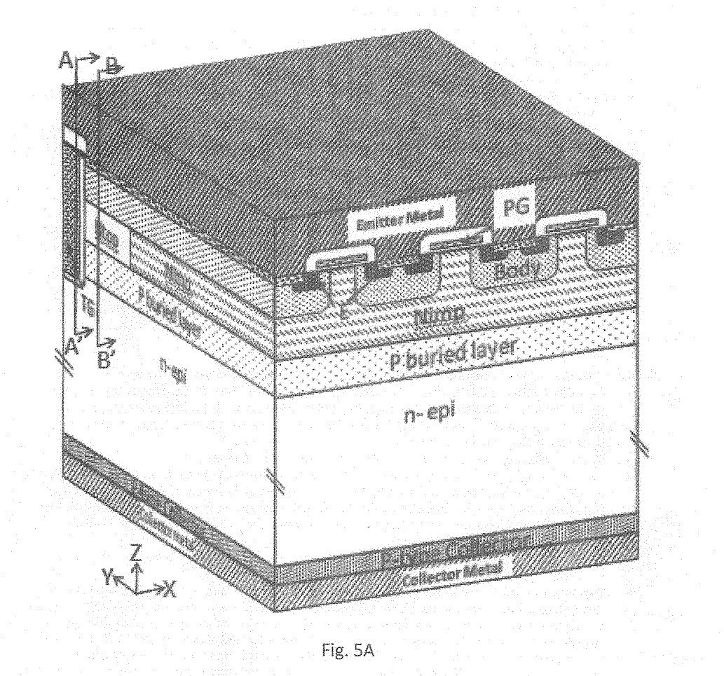

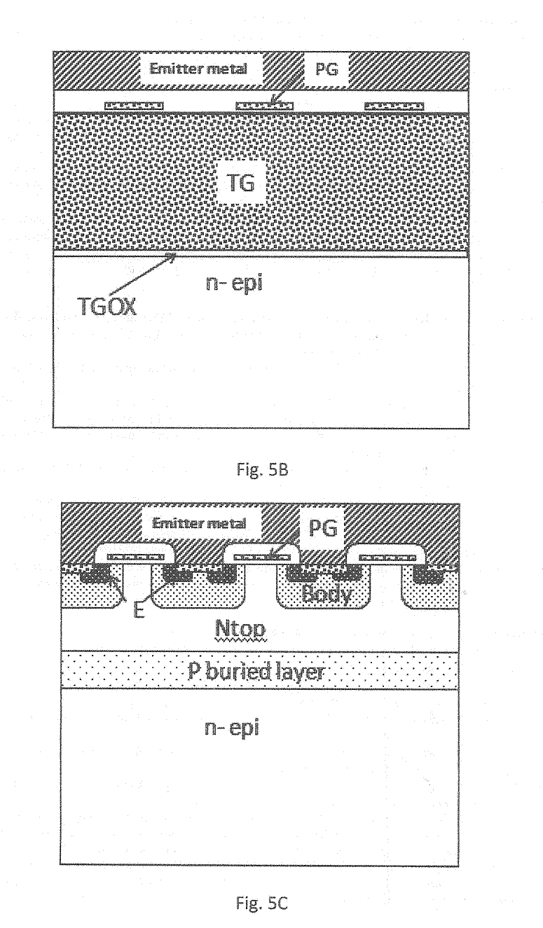

FIG. 4A is a top view and FIGS. 4B to 4E are cross sectional views of the IGBT device along the cross-sectional lines A-A′, B-B′, C-C′ and D-D′ respectively. FIG. 4A shows the IGBT device has a core cell area 101 and a termination area 102. The top layer of the core cell area is covered by the emitter pad. i.e., the emitter metal layer 180. A gate metal 135′ is formed near the edge of the core cell area adjacent to the termination area 102. FIGS. 4B to 4E show the cross section views of the IGBT device along different cross-sectional lines. As shown in these Figures, the trench gate 135 is padded on the sidewalls and the bottom with a trench gate oxide (TGOX) layer 148 and the planar gate is insulated by a planar gate oxide layer 142 underneath the planar gate 140. In FIG. 4B, the trench gate 135 is connected to the gate metal 135′ and in FIG. 4E, the planar gate 140 is connected to the gate pad 135′. FIG. 5A shows a three dimensional perspective view of a new three-dimensional embodiment of this invention, in which the trench 156 is formed along a perpendicular direction relative to the planar gate 140. FIG. 5B and FIG. 5C are cross sectional views of the three-dimensional IGBT alone the cross-sectional lines A-A′ and B-B′ respectively in the X-Z plane. In this embodiment, there is no design limitation for the pitch of the trench gate 135 and also is independent of the pitch of the planar gates 140. Since the planar gate 140 and the trench gate 135 are both connected to the gate metal 135 formed near the termination, the control and operation of the 3 dimensional embodiment is the same.

Although the present invention has been described in terms of the presently preferred embodiment, it is to be understood that such disclosure is not to be interpreted as limiting. For example, though the conductivity types in the examples above often show an n-channel device, the invention can also be applied to p-channel devices by reversing the polarities of the conductivity types. Various alterations and modifications will no doubt become apparent to those skilled in the art after reading the above disclosure. Accordingly, it is intended that the appended claims be interpreted as covering all alterations and modifications as fall within the true spirit and scope of the invention.

I claim:

1. An insulating gate bipolar transistor (IGBT) device comprising:
a substrate including an epitaxial layer of a first conductivity type disposed on top of a bottom semiconductor layer of a second conductivity type wherein the epitaxial layer of the first conductivity type supports a buried layer of a second conductivity type disposed below a top layer of the first conductivity type;
a plurality of MOS transistor cells each having a planar gate disposed on a top surface of the top layer wherein each of the planar gates extended between two adjacent body regions of the second conductivity type encompassing a emitter region of the first conductivity type wherein the body regions and emitter regions are near a top portion of the top layer of the first conductivity type;
a trench gate vertically extending from the top surface of the top layer adjacent to one of the body regions downwardly to the buried layer of the second conductivity with the trench depth deeper than the bottom surface of the buried layer of the second conductivity; and
a lightly doped region in the top layer of the first conductivity type is disposed next to the trench gate below the body region of the second conductivity type above the buried layer of the second conductivity type.

2. the semiconductor power device of claim 1 wherein:
the trench gate is filled with a conductive gate material and padded with a dielectric layer.

3. the semiconductor power device of claim 1 wherein:
each of the planar gates is padded with a gate insulation layer disposed between the top surface of the top layer and the planar gate.

4. the semiconductor power device of claim 1 wherein:
the buried layer of a second conductivity type is electrically floating.

5. the semiconductor power device of claim 1 wherein:
the lightly doped region in the top layer having a dopant concentration of the first conductivity type lower than 50% of the dopant concentration of the highly doped region in the top layer.

6. the semiconductor power device of claim 1 wherein:
the buried layer of the second conductivity type near a sidewall of the trench gate further forming an inversion layer for electrically connecting the top layer to the bottom semiconductor layer of a first conductivity type when a positive voltage is applied to a gate pad to turn on the power device.

7. the semiconductor power device of claim 1 wherein:
a dopant concentration of the buried layer of the second conductivity type near the trench gate is adjusted with a fixed thickness of a gate insulation padding of the trench gate to make a threshold voltage of the trench gate lower than a threshold voltage of the planar gates.

8. the semiconductor power device of claim 1 wherein:
a thickness of a gate insulation padding of the trench gate is adjusted with a fixed dopant concentration of the buried layer of the second conductivity type near the trench gate to make a threshold voltage of the trench gate lower than a threshold voltage of the planar gates.

9. the semiconductor power device of claim 1 wherein:
the trench gate is electrically connected to the planar gates through a connection in a termination area of the IGBT device.

10. the semiconductor power device of claim 1 wherein:
the body regions further comprise an emitter electrode contact dopant region disposed between two emitter regions for electrically contacting an emitter electrode disposed on top of the top layer for contacting the contract dopant regions through openings between the planar gates.

11. the semiconductor power device of claim 1 wherein:
the body regions further comprise an emitter electrode contact dopant region disposed between two emitter regions for electrically contacting an emitter electrode disposed on top of the top layer for contacting the contract dopant regions through openings between the planar gates.

12. the semiconductor power device of claim 1 wherein:
the lateral width of the light doped top region that separates the gate trench from the top layer of the first conductivity type is more than half-pitch of the MOS transistor cells.

13. the semiconductor power device of claim 1 wherein:
the dopant concentration of the highly doped top layer of the first conductivity type is higher than 1e16 cm−3 and the dopant concentration of the lightly doped region adjacent to the trench gate is approximately 1e15 cm−3.

14. the semiconductor power device of claim 1 wherein:
the dopant concentration of the top layer of the first conductivity type is higher than 1e16 cm−3 and the dopant concentration of the lightly doped region adjacent to the trench gate is lower than 50% of the dopant concentration of the top layer of the first conductivity type.

15. the semiconductor power device of claim 1 further comprising:
an electrode disposed on a bottom surface of the bottom semiconductor layer of the second conductivity type as a collector of the IGBT device.

16. the semiconductor power device of claim 1 wherein:
the trench gate extends along a longitudinal direction perpendicular to the planar gate whereby the trench gate has a pitch independent from a pitch of the planar gate.

17. the semiconductor power device of claim 1 wherein:
the trench gate and the planar gates are electrically connected at a periphery of an active cell area wherein the MOS transistor cells are disposed.

18. the semiconductor power device of claim 1 wherein:
the trench gate extends along a longitudinal direction parallel to the planar gate and has a longer pitch size than the pitch of the planar gate so that at least two planar gate MOS transistor cells are included between every two adjacent trench gates.

19. A method for manufacturing an insulating gate bipolar transistor (IGBT) device comprising:
preparing a substrate by forming a semiconductor layer of a first conductivity type on top of a bottom semiconductor layer of a second conductivity type followed by forming a buried layer of a second conductivity type then depositing a top layer of the first conductivity type;
applying a mask to implant and drive-in a top implant region followed by removing the mask thus separating the top layer of first conductivity layer into the top implant region disposed next to a lightly doped top region disposed above the buried layer of the second conductivity type;
forming a trench gate next to the lightly doped top region having a depth extending vertically deeper than a bottom surface of the buried layer of the second conductivity; and
forming a plurality of MOS transistor cells each having a planar gate disposed on a top surface of the top implant region wherein each of the planar gates extended between two adjacent body regions of the second conductivity type encompassing a emitter region of the first conductivity type and wherein the body regions and emitter regions are near a top portion of the top implant region of the first conductivity type.

20. The method of claim 18 wherein:
the step of forming the buried layer of a second conductivity type is a step of forming the buried layer of the second conductivity type as an electrically floating region.

21. The method of claim 18 wherein:
the step of forming the top lightly doped region in the top layer further comprising a step of forming the top light doped region having a dopant concentration of the first conductivity type lower than 50% of dopant concentration of the top highly doped implant region.

22. The method of claim 18 further comprising a step of:
adjusting a dopant concentration of the buried layer of the second conductivity type near the trench gate with a fixed thickness of a gate insulation padding of the trench gate to make a threshold voltage of the trench gate lower than a threshold voltage of the planar gates.

23. The method of claim 18 further comprising:
adjusting a thickness of a gate insulation padding of the trench gate with a fixed dopant concentration of the buried layer of the second conductivity type near the trench gate to make a threshold voltage of the trench gate lower than a threshold voltage of the planar gates.

24. The method of claim 18 wherein:
the step of forming the trench gate and the plurality of MOS transistors each having a planar gate further comprising a step of forming the trench gate to extend along a longitudinal direction perpendicular to the planar gates whereby the trench gate has a pitch independent from a pitch of the planar gate.

25. The method of claim 18 wherein:
the step of forming the trench gate and the plurality of MOS transistors each having a planar gate further comprising a step of disposing the MOS transistor cells in an active cell area and forming the trench gate and the planar gates to electrically connect at a periphery of the active cell area.

26. The method of claim 18 wherein:
the step of forming the trench gate and the plurality of MOS transistors each having a planar gate further comprising a step of forming the trench gate to extend along a longitudinal direction substantially parallel to the planar gates with a longer pitch size than the pitch of the planar gate so that at least two planar gate MOS transistor cells are included between every two adjacent trench gates.
